(19) United States
(12) Patent Application Publication
(10) Pub. No.: US 2009/0268459 A1
(43) Pub. Date: Oct. 29, 2009

(54) LIGHT EMITTING DIODE LAMP

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/211,824

(22) Filed: Sep. 17, 2008

(30) Foreign Application Priority Data
Apr. 23, 2008 (CN) 200810066778.7

(51) Int. Cl. F21V 7/00; H01L 33/00

(52) U.S. Cl. 362/240; 438/27; 257/E33.067

(57) ABSTRACT

An LED lamp includes a base, a plurality of LEDs arranged on the base, and a cover. Each LED has an emitting surface. The cover includes a mounting side attached to the base, and an opposite emitting side. A plurality of blind holes extends into the cover from the mounting side of the cover, and encases the plurality of LEDs therein, respectively. Each blind hole includes an open side facing the base, an opposite closed side facing the emitting surface of the LED, and a sidewall arranged between the open side and the closed side of the blind hole. An area of the closed side of each hole exceeds that of the open side of the blind hole. The sidewall surrounds the LED and reflects light of the LED to the closed side of the blind hole of the cover.

### BACKGROUND

1. Field of the Disclosure

The disclosure generally relates to a light emitting diode lamp, and particularly to a light emitting diode lamp with uniform light distribution.

2. Description of Related Art

In recent years, light emitting diodes (LED) have been widely used in illumination. However, the LED is a point light source, and an emitting surface thereof is usually hemispherical. Intensity of a light field of the LED decreases gradually and outwardly along a radial direction thereof. The intensity of the light field of the LED is uneven, being strong at a center of the light field of the LED and weak at the periphery.

For the foregoing reasons, therefore, there is a need in the art for a new LED lamp which overcomes the limitations described.

### SUMMARY

According to an exemplary embodiment of the disclosure, a light emitting diode lamp includes a base, a plurality of light emitting diodes arranged on the base separately for emitting light, and a cover encasing the light emitting diodes. Each light emitting diode has an emitting surface. The cover includes a mounting side attached to the base, and an opposite emitting side. A plurality of blind holes extends into the cover from the mounting side of the cover, and encases the plurality of light emitting diodes therein, respectively. Each blind hole includes an open side facing the base, an opposite closed side facing the emitting surface of the light emitting diode, and a sidewall arranged between the open side and the closed side of the blind hole. An area of the closed side of each hole exceeds that of the open side of the blind hole. The sidewall surrounds the light emitting diode and reflects light of the light emitting diode to the closed side of the blind hole of the cover.

Other advantages and novel features of the disclosure will be drawn from the following detailed description of the exemplary embodiments of the disclosure with attached drawings.

### BRIEF DESCRIPTION OF THE DRAWINGS

FIG. 1 is an assembled cross section of a light emitting diode lamp according to an exemplary embodiment.

FIG. 2 is an exploded view of the light emitting diode lamp of FIG. 1.

FIG. 3 is a cross section of the light emitting diode lamp of an alternative embodiment.

FIG. 4 is a cross section of the light emitting diode lamp according to a third embodiment.

### DETAILED DESCRIPTION OF THE EMBODIMENTS

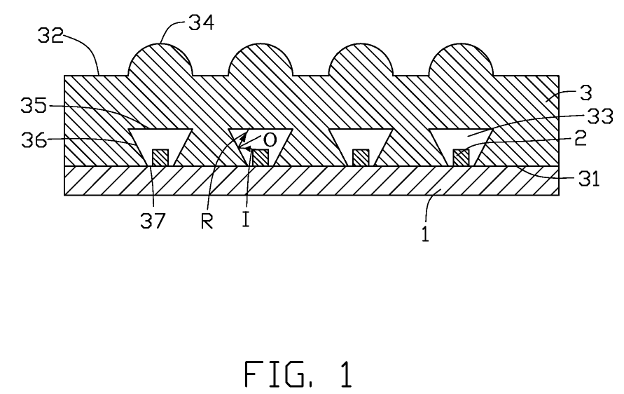

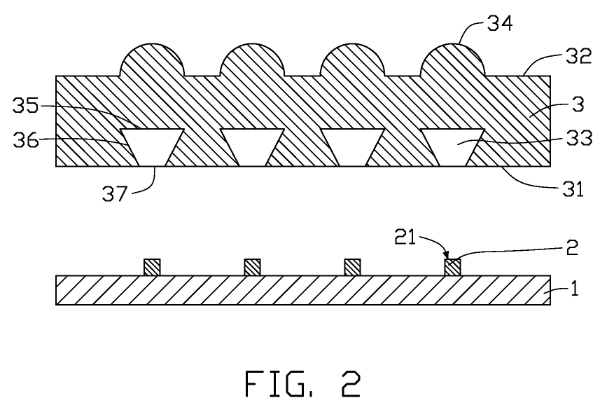

Referring to FIGS. 1 and 2, a light emitting diode lamp according to an exemplary embodiment includes a base 1, a plurality of light emitting diodes 2 (LEDs), and a cover 3.

The base 1 is a circuit board. The cover 3 is arranged on the base 1. A bottom side of the cover 3 forms a mounting side 31 which attaches to the base 1 closely to form an airtight seal therebetween. A top side of the cover 3 forms an emitting side 32 of the cover 3. A plurality of blind holes 33 extend into the cover 3 from the mounting side 31 of the cover 3. The plurality of LEDs 2 is received in the plurality of blind holes 33 of the cover 3, respectively. The electrodes of each LED 2 are electrically connected to the base 1, with electrical current supplied to the LEDs 2 therethrough. Each LED 2 has an emitting surface 21 facing the emitting side 32 of the cover 3.

The cover 3 is made of transparent materials, such as resin or glass. The blind holes 33 are separately arranged on the cover 3, and spaced from each other. Each hole 33 has a depth less than the height of the cover 3, and thus forms an open side 37 at the mounting side 31 of the cover 3, a closed side 35 adjacent to the emitting side 32 of the cover 3, and an annular sidewall 36 between the open side 37 and the closed side 35. In this embodiment, each blind hole 33 is conversely truncated conical. The open side 37 and the closed side 35 of the blind hole 33 are circular, and the sidewall 36 has a shape of sector ring in an unfurled view. A cross section of the blind hole 33 increases gradually and linearly along an axis of the blind hole 33 from the open side 37 to the closed side 35. In other words, the open side 37 of the blind hole 33 is smaller than the closed side 35, and the sidewall 36 expands along the axis from the open side 37 to the closed side 35 of the blind hole 33. The sidewall 36 is coated with a layer of material of high reflectivity, such as mercury.

The LED lamp includes a base 1 and a plurality of LEDs 2 electrically connected to the base 1. It is to be understood that the modality of the LEDs 2 of the LED lamp is predetermined, and the modality of the LEDs 2 of different LED lamps can be different from each other. A cover 3 with a plurality of blind holes 33 formed therein attaches to the base 1 and encases the LEDs 2 in the blind holes 33 thereof, respectively. Since all of the LEDs 2 can be assembled at the same time to form the LED lamp, fabrication is thus simple and fast. Size and a position of the blind holes 33 of the cover 3 are decided according to the modality of the LEDs 2. The LED 2 arranged in each blind hole 33 is located at the central axis of the blind hole 33. A plurality of lenses 34 are arranged on the emitting side 32 of the cover 3 corresponding to the plurality of LEDs 2. The lenses 34 are integrally formed with the cover 3. Each lens 34 is located on the central axis of one corresponding blind hole 33. A center of the emitting surface 21 of the LED 2, a center of the open side 37, and a center of the closed side 35 of the blind hole 33 which receives the LED 2, and a center of the lens 34 over the LED 2 are collinear.

When the LED 2 emits light, part of the light travels towards the closed side 35 of the blind hole 33 directly and then passes across the cover 3 to the outside, and part of the light of the LED 2 travels towards the sidewall 36 of the blind hole 33 of the cover 3. As shown in FIG. 1, due to the sidewall 36 being coated with high reflectivity material, when light emitted towards the sidewall 36, that is, incident light I, approaches the sidewall 36 of the blind hole 33, the light is reflected towards the closed side 35 of the blind hole 33 of the cover 3, that is, reflected light R. An angle of incidence is defined between the incident light I and the normal O perpendicular to the point at which the incident light I reaches the sidewall 36, and an angle of reflection is defined between the reflected light R and the normal O. The angle of incidence is equal to the angle of reflection.

As the sidewall 36 of the blind hole 33 of the cover 3 expands inwardly along the central axis of the blind hole 33, with an angle between the closed side 35 and the sidewall 36 of the blind hole 33 less than 90°, and an angle between the open side 37 and the sidewall 36 of the blind hole 33 exceeding 90°. Thus, when the light of the LED 2 travels towards the sidewall 36, the reflected light R, which is symmetrical to the incident light I about the normal O, is located over the normal O. The incident light I is thus reflected to the closed side 35 of the blind hole 33 of the cover 3 by the sidewall 36. The closed side 35 of the blind hole 33 of the cover 35 acts as an incident side of the cover 3. Thus approximately all of the light of the LED 2 passes across the incident side and thus enters into the cover 3 and finally out through the cover 3 to the outside. The direction of all of the light is towards the emitting surface 21 of the cover 3, and thus the LED 2 likes a surface light source. An intensity of the light field of the LED 2 thus is substantially even. In addition, the lens 34 formed on the emitting surface 21 of the cover 3 enhances light emitting directionality of the LED 2. The lens 34 is located at the central axis of the LED 2, and can converge the light of the LED 2; thus, the light emitted from the lens 34 is approximately parallel light. Thus the LED lamp has high directionality.

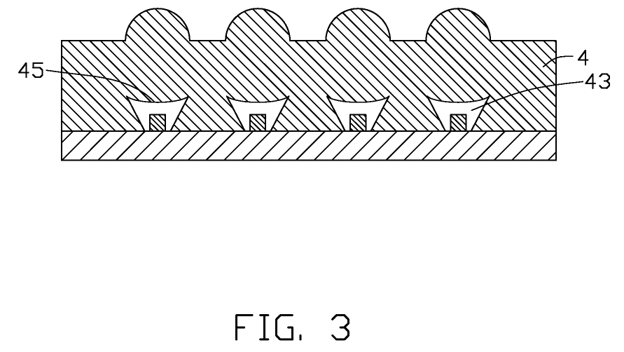

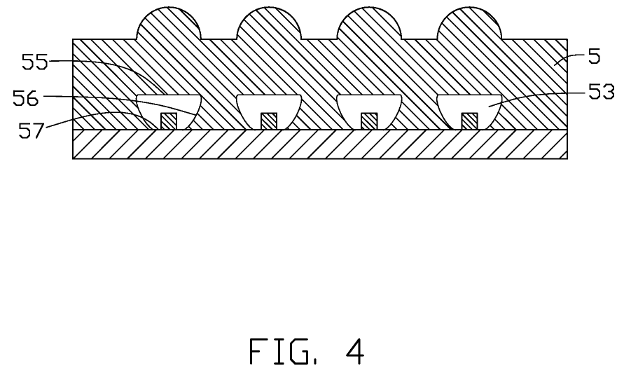

The cover 3 may be embodied in other forms without departing from the spirit of the disclosure. FIG. 3 shows an alternative embodiment of the of the LED lamp differing from the previous embodiment is that the blind hole 43 of the cover 4 forms a concave closed side 45, whereby the cover 4 forms a convex incident side at the closed side 45 of each blind hole 43. FIG. 4 shows a third embodiment of the LED lamp. In this embodiment, each blind hole 53 of the cover 5 is concave. A cross section of the blind hole 53 increases along the central axis of the blind hole 53 from the open side 57 to the closed side 55 nonlinearly. The sidewall 56 of the blind hole 53 is curved.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode lamp, comprising:
a base;
a plurality of light emitting diodes arranged on the base separately for emitting light, each light emitting diode having an emitting surface; and
a cover comprising a mounting side attaching to the base and an opposite emitting side, a plurality of blind holes extending into the cover from the mounting side of the cover and receiving the plurality of light emitting diodes therein, respectively, each blind hole comprising an open side facing the base, an opposite closed side facing the emitting surface of the light emitting diode, and a sidewall arranged between the open side and the closed side of the blind hole, the sidewall surrounding a corresponding light emitting diode for reflecting light of the corresponding light emitting diode to the closed side of the blind hole of the cover, an area of the closed side of each blind hole exceeding that of the open side of the blind hole.

2. The light emitting diode lamp of claim 1, wherein the mounting surface of the cover and the base form an airtight seal around the light emitting diodes.

3. The light emitting diode lamp of claim 1, wherein a plurality of lenses is arranged on the emitting surface of the cover corresponding to the plurality of blind holes, each lens being arranged on a central axis of a corresponding blind hole.

4. The light emitting diode lamp of claim 3, wherein the central axis of the corresponding blind hole is collinear with a central axis of the emitting surface of a corresponding light emitting diode received in the corresponding blind hole.

5. The light emitting diode lamp of claim 1, wherein each blind hole is conversely truncated conical, the open side and the closed side of the each blind hole being circular, and the sidewall having a shape of sector ring in an unfurled view.

6. The light emitting diode lamp of claim 1, wherein the closed side of the each blind hole is concave.

7. The light emitting diode lamp of claim 1, wherein each blind hole is concave.

8. A light emitting diode lamp, comprising:
a base;
a plurality of light emitting diodes electrically connected to the base; and
a cover having a mounting side attach to the base closely to form an airtight seal therebetween, a plurality of blind holes extending into the cover from the mounting side of the cover and receiving the plurality of light emitting diodes therein, respectively, each mounting hole expanding along an axis thereof away from the mounting side.

9. The light emitting diode lamp of claim 8, wherein each blind hole forms an open side at the mounting side of the cover, a closed side opposite to the open side, and a sidewall between the open side and the closed side for reflecting the light of a corresponding light emitting diode to the closed side.

10. The light emitting diode lamp of claim 9, wherein each blind hole has a conversed truncated cone shape, the open side and the closed side of the each blind hole being circular, and the sidewall has a shape of sector ring in an unfurled view.

11. The light emitting diode lamp of claim 9, wherein each blind hole is concave.

12. The light emitting diode lamp of claim 9, wherein the closed side of the each blind hole is concave.

13. The light emitting diode lamp of claim 8, wherein the cover forms a lens on a side opposite to the mounting surface corresponding to each light emitting diode.

14. A method for fabricating a light emitting lamp, comprising:
providing a base and a plurality of light emitting diodes;
connecting the plurality of light emitting diodes to the base electrically;
providing a cover formed with a plurality of blind holes in the cover, each blind hole extending into the cover from a first side thereof;
attaching the cover to the base closely, the first side of the cover and the base forming an airtight seal therebetween, the blind holes of the cover encasing the light emitting diodes, respectively.

15. The method of claim 14, wherein the blind holes formed in the cover each expand along an extending axis thereof.
